(19) United States
(12) Patent Application Publication
(10) Pub. No.: US 2026/0142557 A1
(43) Pub. Date: May 21, 2026

(54) POWER CONVERSION DEVICE

(71) Applicant: DENSO CORPORATION, Kariya-city (JP)

(72) Inventors: Atsuki Asano, Kariya-city (JP); Yoshinori Hayashi, Kariya-city (JP); Akira Tokumasu, Kariya-city (JP)

(73) Assignee: DENSO CORPORATION, Kariya-city (JP)

(21) Appl. No.: 19/449,708

(22) Filed: Jan. 15, 2026

Related U.S. Application Data
(63) Continuation of application No. PCT/JP2024/028230, filed on Aug. 7, 2024.

(30) Foreign Application Priority Data
Aug. 10, 2023 (JP) 2023-131628

(51) Int. Cl. H02M 1/088; H02M 7/539; H02P 29/024; H03K 17/082

(52) U.S. Cl. CPC H02M 1/088; H02M 7/539; H02P 29/0241; H03K 17/0822

(57) ABSTRACT

A power conversion device includes a MOSFET that is a switching element, an ECU that is a control device that commands the switching speed of the switching element, and a drive circuit that drives the switching element to turn on and off at a switching speed corresponding to a command speed. The power conversion device includes a feedback circuit as a feedback function, and a monitoring unit as an abnormality determination unit. A feedback circuit outputs a signal correlated with an actual switching speed as a feedback signal to the control device. An abnormality determination unit determines whether the actual switching speed is in an abnormal state contrary to the command speed by comparing the feedback signal with the command speed.

### CROSS REFERENCE TO RELATED APPLICATIONS

The present application is a continuation application of International Patent Application No. PCT/JP2024/028230 filed on August 7, 2024, which designated the U.S. and claims the benefit of priority from Japanese Patent Application No. 2023-131628 filed in Japan filed on August 10, 2023, the entire disclosure of the above application is incorporated herein by reference.

### TECHNICAL FIELD

The present disclosure relates to a power conversion device.

### BACKGROUND ART

A power conversion device in which a switching speed of a switching element can be changed is known.

### SUMMARY

One disclosed object is to provide a power conversion device that can reduce a risk of damage to switching element while improving power consumption by making the switching speed variable.

A power conversion device according to one aspect includes: a plurality of switching elements that convert and output electric power, a control device that commands a switching speed of the switching element, a drive circuit that drives the switching element to turn on and off at a switching speed corresponding to a command speed from the control device, a feedback unit that outputs a signal correlated with an actual switching speed as a feedback signal to the control device, and an abnormality determination unit that determines whether the actual switching speed is in an abnormal state contrary to the command speed by comparing the feedback signal with the command speed.

### BRIEF DESCRIPTION OF THE DRAWINGS

FIG. 1 is a diagram showing a circuit configuration and a drive system of a power conversion device according to a first embodiment;

FIG. 2 is a diagram showing a configuration of a drive circuit and an ECU;

FIG. 3 is a diagram showing differences in voltage waveforms depending on switching speeds;

FIG. 4 is a diagram showing a relationship between surge voltage and power loss;

FIG. 5 is a flowchart showing a process executed by a microcomputer of the ECU;

FIG. 6 is a flowchart showing a process executed by a microcomputer according to a second embodiment; and

FIG. 7 is a flowchart showing a process executed by a microcomputer according to a third embodiment.

### DETAILED DESCRIPTION

A power conversion device in which a switching speed of a switching element can be changed is known. The description contents of Patent Document (JP 2015-65742 A) are incorporated by reference as the description of technical elements in this specification.

In a power conversion device having a variable switching speed as described above, the power consumption can be improved by increasing the switching speed. However, the faster the switching speed, the larger the surge voltage becomes, which raises concerns about damage to the switching element.

One disclosed object is to provide a power conversion device that can reduce a risk of damage to switching element while improving power consumption by making the switching speed variable.

A power conversion device according to one aspect includes: a plurality of switching elements that convert and output electric power, a control device that commands a switching speed of the switching element, a drive circuit that drives the switching element to turn on and off at a switching speed corresponding to a command speed from the control device, a feedback unit that outputs a signal correlated with an actual switching speed as a feedback signal to the control device, and an abnormality determination unit that determines whether the actual switching speed is in an abnormal state contrary to the command speed by comparing the feedback signal with the command speed.

According to the disclosed power conversion device, the switching elements are turned on and off at a switching speed corresponding to the command speed, so that the switching speed can be changed. Therefore, by increasing the switching speed, it is possible to improve the power consumption. At the same time, the abnormality determination unit determines whether the actual switching speed is in an abnormal state contrary to the command speed, so that it is possible to implement measures to deal with abnormalities such as fail-safe control. Therefore, the risk of damage to the switching element can be reduced.

The multiple embodiments disclosed in this specification employ different technical means to achieve their respective objectives. The objects, features, and advantageous effects disclosed in this description will become more apparent with reference to the following detailed description and accompanying drawings.

Hereinafter, multiple embodiments will be described with reference to the drawings. The same reference numerals are assigned to the corresponding elements in each embodiment, and thus, duplicate descriptions may be omitted. When only a part of the configuration is described in the respective embodiments, the configuration of the other embodiments described before may be applied to other parts of the configuration. Further, it is possible to not only combine configurations as specified in the description of the embodiments but also partially combine configurations of embodiments even though not specified herein as long as the combination does not cause difficulty.

The power conversion device according to the present embodiment is applicable to, e.g., a movable object with a rotary electric machine as a drive source. The movable object is, for example, an electrically driven vehicle such as an electric vehicle (BEV), a hybrid vehicle (HEV), or a plug-in hybrid vehicle (PHEV), an electric flying object, a ship, a construction machine, or an agricultural machine. The electric flying object may be, for example, a drone or an electric vertical takeoff and landing aircraft (eVTOL). Hereinafter, an example applied to a vehicle will be described.

### First Embodiment:

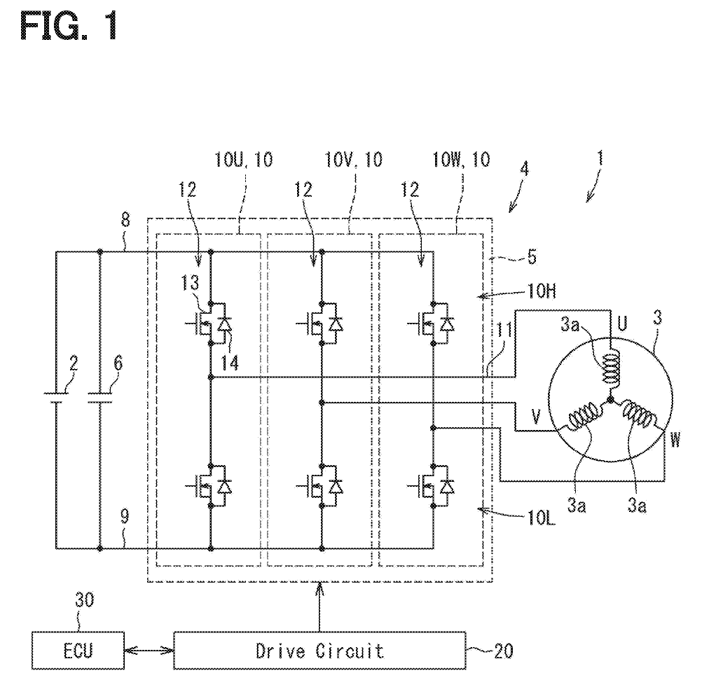

First, a schematic configuration of a vehicle drive system is described with reference to FIG. 1.

Vehicle Drive System 1:

As shown in FIG. 1, the vehicle drive system 1 is provided with a direct current (DC) power supply 2, a motor generator 3, and a power conversion device 4.

The DC power supply 2 is a direct-current voltage source including a chargeable and dischargeable secondary battery. The secondary battery may be a lithium ion battery, a nickel-hydrogen battery, or an organic radical battery. The motor generator 3 is a three-phase AC type rotating electric machine. The motor generator 3 functions as a vehicle driving power source, i.e., an electric motor. The motor generator 3 functions as a generator during regeneration. The power conversion device 4 performs electric power conversion between the DC power supply 2 and the motor generator 3.

Circuit Configuration of Power Conversion Device 4:

FIG. 1 shows a circuit configuration of the power conversion device 4. The power conversion device 4 includes at least a power conversion circuit. The power conversion device in the present embodiment is an inverter 5. The power conversion device 4 further includes a smoothing capacitor 6, a drive circuit 20, an ECU 30 (control device), and the like. ECU is an abbreviation of Electronic Control Unit.

The smoothing capacitor 6 mainly smooths the DC voltage supplied from the DC power supply 2. The smoothing capacitor 6 is connected between a P-line 8 which is a power line on a high potential side and an N-line 9 which is a power line on a low potential side. The P-line 8 is connected to a positive electrode of the DC power supply 2, and the N-line 9 is connected to a negative electrode of the DC power supply 2. The positive electrode of the smoothing capacitor 6 is connected to the P line 8 between the DC power supply 2 and the inverter 5. The negative electrode of the smoothing capacitor 6 is connected to the N-line 9 at a position between the DC power supply 2 and the inverter 5. The smoothing capacitor 6 is connected in parallel with the DC power supply 2.

The inverter 5 is a DC-AC conversion circuit. The inverter 5 converts the DC voltage into a three-phase AC voltage according to a switching control by the ECU 30 and outputs the three-phase AC voltage to the motor generator 3. Thereby, the motor generator 3 is driven to generate a predetermined torque. At the time of regenerative braking of the vehicle, the inverter 5 converts the three-phase AC voltage generated by the motor generator 3 by receiving the rotational force from the wheels into a DC voltage according to the switching control by the ECU 30, and outputs the DC voltage to the P line 8. In this way, the inverter 5 performs bidirectional power conversion between the DC power supply 2 and the motor generator 3.

The inverter 5 is configured with upper and lower arm circuits 10 for each of the three phases. The upper and lower arm circuits 10 may be referred to as legs. Each of the upper and lower arm circuits 10 has an upper arm 10H and a lower arm 10L. The upper arm 10H and the lower arm 10L are connected in series between the P-line 8 and the N-line 9, with the upper arm 10H positioned on the P-line 8 side.

A connection point between the upper arm 10H and the lower arm 10L, i.e., a midpoint of the upper and lower arm circuit 10, is connected to a winding 3a of the corresponding phase in the motor generator 3 via an output line 11. Of the upper and lower arm circuits 10, the U-phase upper and lower arm circuit 10U is connected to the U-phase winding 3a via the output line 11. The V-phase upper and lower arm circuit 10V is connected to the V-phase winding 3a via the output line 11. The W-phase upper and lower arm circuit 10W is connected to the W-phase winding 3a via the output line 11.

The upper and lower arm circuits 10 (10U, 10V, 10W) have a series circuit 12. The series circuit 12 included in the upper and lower arm circuits 10 may be a single circuit or may be multiple circuits. In the case of a plurality of series circuits 12, the series circuits 12 are connected in parallel to each other to form the upper and lower arm circuit 10 for one phase. In the present embodiment, each of the upper and lower arm circuits 10 has one series circuit 12. The series circuit 12 is configured by connecting a switching element on the upper arm 10H side and a switching element on the lower arm 10L side in series between the P line 8 and the N line 9.

The number of switching elements on the high side and the number of switching elements on the low side constituting the series circuit 12 are not particularly limited. The number thereof may be one or more. The series circuit 12 of the present embodiment has one switching element on the high side and one switching element on the low side.

In the present embodiment, an n-channel MOSFET 13 is used as each switching element. MOSFET is an abbreviation for Metal Oxide Semiconductor Field Effect Transistor. The MOSFET 13 is turned on and off by a drive signal (gate voltage).

A freewheeling diode 14 (hereinafter, referred to as FWD 14) is connected in anti-parallel to each of the MOSFETs 13. In the case of the MOSFET 13, the FWD 1 may be a parasitic diode (body diode) or an external diode. In the upper arm 10H, the drain of the MOSFET 13 is connected to the P line 8. In the lower arm 10L, the source of the MOSFET 13 is connected to the N line 9. The drain of the MOSFET 13 in the upper arm 10H and the drain of the MOSFET 13 in the lower arm 10L are connected to each other. The anode of the FWD 14 is connected to the source of the corresponding MOSFET 13, and the cathode is connected to the drain.

The switching element is not limited to the MOSFET 13. For example, an IGBT may be used. The IGBT is an abbreviation of an insulated gate bipolar transistor. In the case of the IGBT, the FWD 14 is also connected in inverse parallel. The MOSFET 13 corresponds to a switching element.

The drive circuit 20 drives switching elements that constitute the power conversion circuit such as the inverter 5. The drive circuit 20 supplies a gate voltage to the gate of the corresponding MOSFET 13 based on a drive command from the ECU 30. The drive circuit drives the corresponding MOSFET 13 by applying a gate voltage to turn on and off the drive of the corresponding MOSFET 13. The drive circuit may also be referred to as a driver.

The ECU 30 generates a drive command for operating the MOSFET 13 and outputs the drive command to the drive circuit 20. The ECU 30 generates a drive command based on a torque request input from a host ECU (not illustrated) and signals detected by various sensors. Furthermore, the ECU 30 generates a speed command for changing the switching speed of the MOSFET 13 and outputs it to the drive circuit 20. The ECU 30 may be provided in a host ECU.

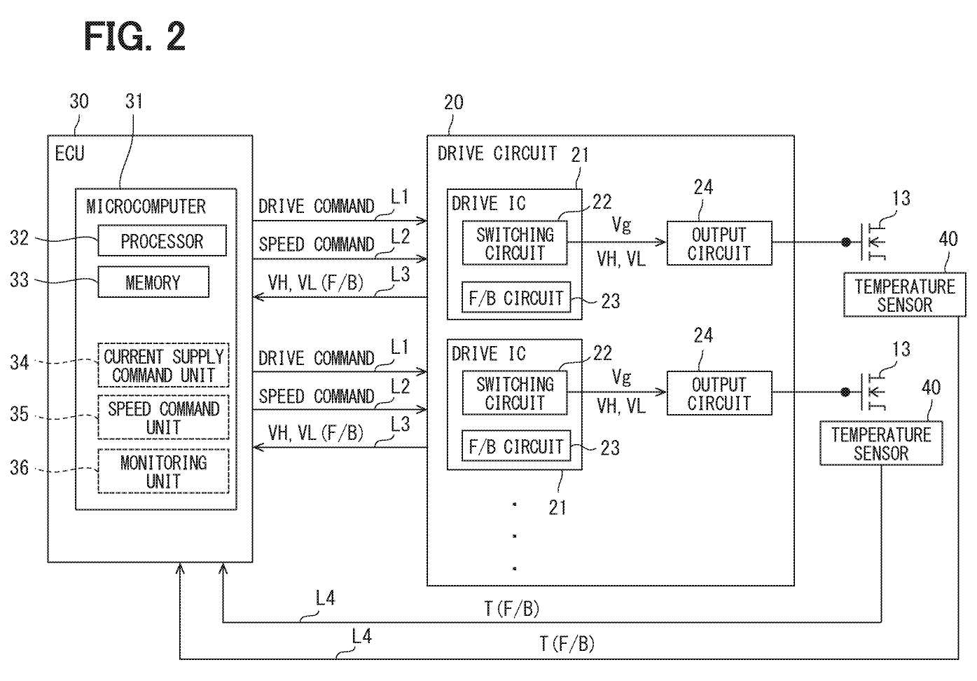

Next, the configuration of the drive circuit 20 and the ECU 30 will be described in more detail with reference to FIG. 2.

The drive circuit 20 includes a drive IC 21 and an output circuit 24. The drive IC 21 functions as a switching circuit 22 and a feedback circuit 23. The output circuit 24 outputs a gate voltage to the gate terminal of the MOSFET 13. The output circuit 24 has a function of switching the magnitude of the gate voltage and outputting it. The switching circuit 22 outputs the drive signal Vg and the switching signals VH and VL to the output circuit 24.

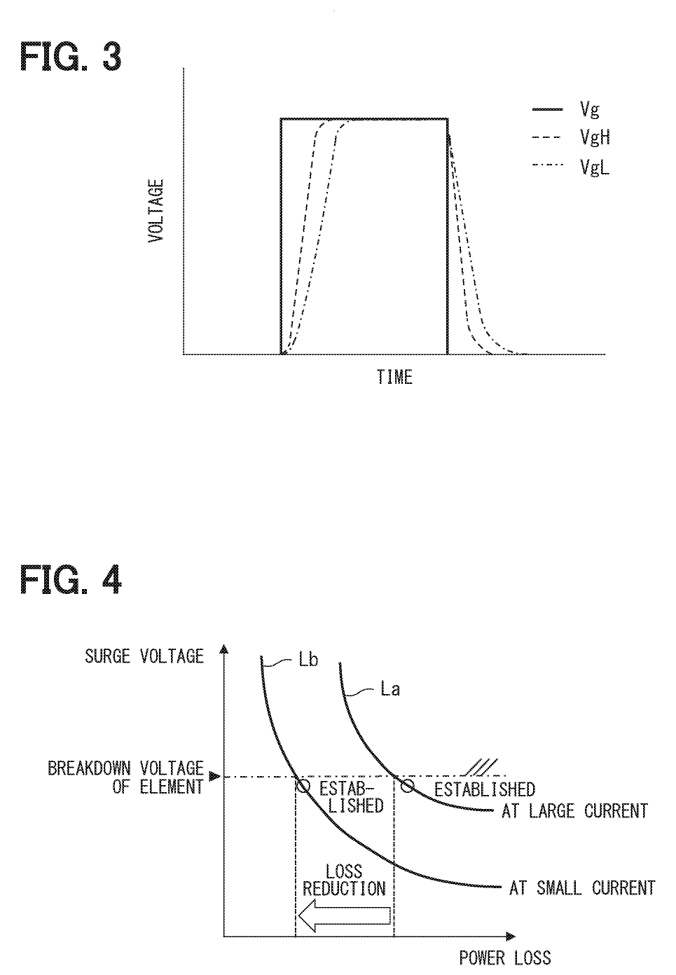

The drive signal Vg is a voltage signal generated in response to a drive command from the ECU 30. The drive signal Vg is a square waveform signal whose voltage changes in a pulse-like manner over time, as shown by the solid line in FIG. 3. With the pulse-on of the drive signal Vg, the MOSFET 13 is turned on and the motor current Im flows through the winding 3a. With the pulse-off of the drive signal Vg, the MOSFET 13 is turned off and the motor current Im becomes zero.

The switching signals VH and VL are voltage signals generated in response to a speed command from the ECU 30. The switching signals VH and VL are signals that instruct the type of waveform into which the drive signal Vg is converted. The dashed line in FIG. 3 is a drive signal converted into a waveform for high-speed switching, which is a high-speed drive signal VgH. The dashed dotted line in FIG. 3 is the drive signal converted into a waveform for low-speed switching, which is the low-speed drive signal VgL.

The output circuit 24 converts the drive signal Vg into the high-speed drive signal VgH when the switching signal VH is commanded, and converts the drive signal Vg into the low-speed drive signal VgL when the switching signal VL is commanded. With the high-speed drive signal VgH, the slope of the pulse edge is steeper compared to the low-speed drive signal VgL. By switching the waveform of the gate voltage in this way, the waveform of the voltage (motor voltage) of the motor current Im flowing through the MOSFET 13 also changes. The rising and falling slopes of the motor voltage are greater in the case of the high-speed drive signal VgH than in the case of the low-speed drive signal VgL.

As used herein, the switching speed refers to the rate of change (i.e., slope) of the rise and fall of the motor voltage. The faster this change rate, that is, the greater the slope, the faster the switching speed becomes, and the less power loss occurs when the MOSFET 13 is turned on and off. On the other hand, the faster the switching speed, the larger the surge voltage that occurs when the MOSFET 13 is switched on and off. In other words, the height of the surge waveform appearing in the motor voltage increases.

For example, in the present embodiment, the MOS transistors are used in the output circuit 24, and the switching signals VH and VL are input to the gates of the MOS transistors. The drive signal Vg input to the MOS transistor is converted into a signal corresponding to the switching signals VH and VL and then output. For example, the switching signal VH is set to a higher voltage than the switching signal VL. When the switching signal VH is input to the output circuit 24, the high-speed drive signal VgH is output from the output circuit 24. As a result, the switching speed of the MOSFET 13 becomes high. When the switching signal VL is input to the output circuit 24, the low-speed drive signal VgL is output from the output circuit 24. As a result, the switching speed of MOSFET 13 becomes slower.

The feedback circuit 23 outputs a signal correlated with the actual switching speed of the MOSFET 13 to the ECU 30 as a feedback signal. The feedback circuit 23 corresponds to a feedback unit. The feedback signal output by the feedback circuit 23 is a signal that indicates the type of the switching signals VH, VL output by the switching circuit 22 to the output circuit 24. For example, when the switching signal VH is output to increase the switching speed, the high-speed signal VH is output as the feedback signal. When the switching signal VL is output to slow down the switching speed, the slow signal VL is output as a feedback signal.

The drive IC 21 and the output circuit 24 are provided for each MOSFET 13. Therefore, a feedback signal is input to the ECU 30 for each of the MOSFETs 13. That is, a plurality of feedback signals are input to the ECU 30.

Furthermore, in the present embodiment, in addition to the high-speed signal VH and the low-speed signal VL, an element temperature T is also input to the ECU 30 as a feedback signal. The element temperature T is the temperature of the MOSFET 13 detected by the temperature sensor 40. The faster the switching speed, the higher the element temperature T becomes. In other words, the element temperature T is a signal that correlates with the actual switching speed of the MOSFET 13. When the ECU 30 uses the element temperature T as a feedback signal, the temperature sensor 40 corresponds to a feedback unit.

The ECU 30 includes a microcomputer 31. The microcomputer 31 includes a processor 32 and a memory 33. The processor 32 executes the programs stored in the memory 33, causing the microcomputer 31 to perform a variety of functions. These functions include a current supply command unit 34, a speed command unit 35, a monitoring unit 36, and the like.

The current supply command unit 34 generates the drive command described above based on the torque request and signals detected by the various sensors. The current supply command unit 34 outputs, for example, a PWM signal as a drive command. PWM is an abbreviation for Pulse Width Modulation.

As shown in FIG. 4, the surge voltage increases as the switching speed is increased to reduce power loss. When the surge voltage exceeds the breakdown voltage (element breakdown voltage) of the MOSFET 13, there is a concern that the MOSFET 13 may be damaged. When the MOSFET 13 is damaged, the vehicle may become unable to run. Therefore, the speed command unit 35 generates a speed command to increase the switching speed to the extent that the surge voltage does not exceed the breakdown voltage of the element, thereby reducing power loss and avoiding damage to the element.

However, even if the switching speed is the same, the surge voltage increases as the current flowing through the MOSFET 13 increases. Therefore, the speed command unit 35 generates a speed command so that the switching speed is slower as the current flows through the MOSFET 13 to avoid damage to the element.

In consideration of the above points, the speed command unit 35 generates a speed command based on the magnitude of the motor current Im detected by a current sensor (not shown). The motor current Im is the current flowing through the winding 3a of each phase. The speed command is generated so that the switching speed becomes slower as the motor current Im increases. In the present embodiment, the switching speed is switched between two stages: high-speed and low-speed. The speed command unit 35 outputs either a high-speed signal or a low-speed signal as a speed command. The speed command unit 35 commands a common switching speed to the plurality of MOSFETs 13.

The monitoring unit 36 compares the content of the speed command output by the current supply command unit 34 with the actual switching speed, that is, the feedback signal, to monitor whether an abnormal state has occurred. In a normal state, the content of the speed command and the content of the feedback signal should match, and when they do not match, it is determined that an abnormal state has occurred. The feedback signals used for this monitoring may be the low-speed signal VL and the high-speed signal VH, or the element temperature T. The monitoring unit 36 corresponds to an abnormality determination unit.

The monitoring unit 36 according to the present embodiment performs monitoring using the low-speed signal VL and the high-speed signal VH as feedback signals. There are two patterns of abnormal conditions as follows. One is a pattern in which the feedback signal is the low-speed signal VL even though the speed command unit 35 outputs a high-speed signal. The other is a pattern in which the feedback signal is the high-speed signal VH even though the speed command unit 35 outputs a low-speed signal.

One of the causes of the abnormality is a failure of MOSFET 13 itself, including element damage, sticking, disconnection, or short-circuit. Another cause is a failure of the signal lines L1, L2, and L3 connecting the ECU 30 and the drive circuit 20, such as a break or short circuit in the signal lines L1, L2, and L3.

The ECU 30 and the drive circuit 20 can communicate with each other via the signal lines L1, L2, and L3. In the present embodiment, the drive command and the speed command are transmitted over separate signal lines L1 and L2, but they may be transmitted over a common signal line. The low-speed signal VL and the high-speed signal VH as feedback signals are transmitted from the drive circuit 20 to the ECU 30 via a signal line L4. In the present embodiment, the feedback signal corresponding to each of the MOSFETs 13 is transmitted through separate signal lines L3, but may be transmitted through a common signal line.

The temperature sensor 40 and the ECU 30 are connected by the signal line L4. The element temperature T is transmitted from the temperature sensor 40 to the ECU 30 using this signal line L4. Alternatively, the element temperature T may be transmitted from the temperature sensor 40 to the ECU 30 via the drive circuit 20. In this case, the low-speed signal VL, the high-speed signal VH, and the element temperature T may be transmitted from the drive circuit 20 to the ECU 30 using the common signal line. In this case, the signal line for the element temperature T can be used to transmit a feedback signal from the drive circuit 20 to the ECU 30, thereby reducing the number of signal lines.

Control flow by microcomputer 31:

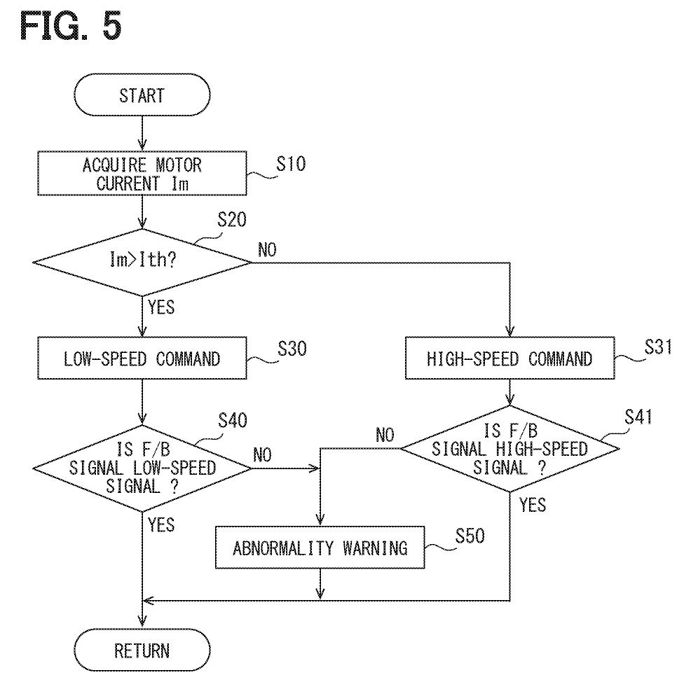

The control flow shown in FIG. 5 is repeatedly executed by the microcomputer 31 at a predetermined calculation period while the motor generator 3 is being driven.

First, in step S10, the detected value of the motor current Im is acquired. In the following step S20, it is determined whether the acquired motor current Im is greater than a threshold value Ith. When it is determined that the acquired motor current Im is greater than the threshold value Ith, it is considered that the current is large as shown in FIG. 4. Then, in the following step S30, the speed command unit 35 outputs the low-speed signal as a speed command. By reducing the surge voltage with this configuration, the damage to the elements of the MOSFET 13 can be avoided.

On the other hand, when it is determined that the acquired motor current Im is not greater than the threshold value Ith, it is considered to be during the low current period shown in FIG. 4. Then, the speed command unit 35 outputs the high-speed signal as a speed command. This increases the switching speed and reduces power loss.

When a low-speed command is issued in step S30, the monitoring unit 36 determines in the following step S40 whether the feedback signal is the low-speed signal VL. When it is determined in step S40 that the feedback signal is the low-speed signal VL, the command speed and the feedback signal coincide, so it is considered to be in a normal state and the process of FIG. 5 is ended.

When a high-speed command is issued in step S31, the monitoring unit 36 determines in the following step S41 whether the feedback signal is the high-speed signal VH. When it is determined in step S41 that the feedback signal is the high-speed signal VH, the command speed and the feedback signal coincide, so it is considered to be in a normal state and the process of FIG. 5 is ended.

As described above, the feedback signal is input from the feedback circuit 23 to the ECU 30 for each of the MOSFETs 13. In the determinations of steps S40 and S41, when at least one of the plurality of feedback signals input to the ECU 30 does not match the command speed, a negative determination is made and the process proceeds to step S50.

When it is determined in step S40 that the feedback signal is the low-speed signal VL, the command speed and the feedback signal do not match. Similarly, when it is determined in step S41 that the feedback signal is the high-speed signal VH, the command speed and the feedback signal do not match. In these cases, it is assumed that an abnormal state exists, and the process proceeds to the next step S50.

In step S50, an abnormal state is diagnosed, and an abnormality flag is set to ON. When the abnormality flag is set to ON, the current supply command unit 34 executes fail-safe control such as limiting the output of the motor generator 3. When the abnormality flag is set to ON, the ECU 30 notifies the host ECU of the abnormal state. Upon receiving the notification of the abnormal state, the host ECU notifies the vehicle occupants of the abnormal state by displaying a warning or outputting a warning sound.

### Summary of First Embodiment:

In the present embodiment, the MOSFET 13 is turned on and off at a switching speed corresponding to the command speed, so the switching speed can be changed. Therefore, by increasing the switching speed, it is possible to improve the power consumption. At the same time, a feedback signal correlated with the actual switching speed is fed back to the ECU 30, so that the ECU 30 can monitor whether the actual switching speed is in an abnormal state contrary to the command speed. Therefore, it is possible to implement measures to deal with abnormalities, such as fail-safe control to limit the output of the motor generator 3, issuing a warning, etc. As a result, while improving power consumption, it is possible to reduce the risk of the surge voltage exceeding the breakdown voltage of the element due to the actual switching speed becoming faster than intended.

In the preset embodiment, the ECU 30 commands the plurality of MOSFETs 13 to switch at a common speed. The feedback circuit 23 outputs a feedback signal to each of the plurality of MOSFETs 13. The monitoring unit 36 determines that an abnormal state exists when at least one of the multiple feedback signals is not in line with the command speed. This reduces the processing load on the microcomputer 31.

Here, when the element temperature T is used as a feedback signal, even if an abnormal state occurs, it takes time for the element temperature T to change to an abnormal temperature. Therefore, it is difficult to quickly detect an abnormality. In contrast, in this embodiment, the drive circuit 20 has an output circuit 24 that switches the magnitude of the gate voltage and outputs it to the gate terminal of the MOSFET 13. The drive circuit 20 further includes the switching circuit 22 that commands the magnitude of the gate voltage to the output circuit 24. The feedback signal used for monitoring by the monitoring unit 36 includes the switching signals VH and VL representing the command content from the switching circuit 22. Therefore, even if an abnormal state occurs in which the content of the speed command and the content of the feedback signal do not match, the abnormality can be detected quickly.

### Second Embodiment:

A second embodiment is a modification of the preceding embodiment as a basic configuration and may incorporate description of the precedent embodiments. In the previous embodiment, even if an abnormality is detected, the command speed is determined according to the magnitude of the motor current Im. Instead, in the present embodiment, when the abnormality is detected, the command speed from the next time onwards is set as follows, regardless of the magnitude of the motor current Im.

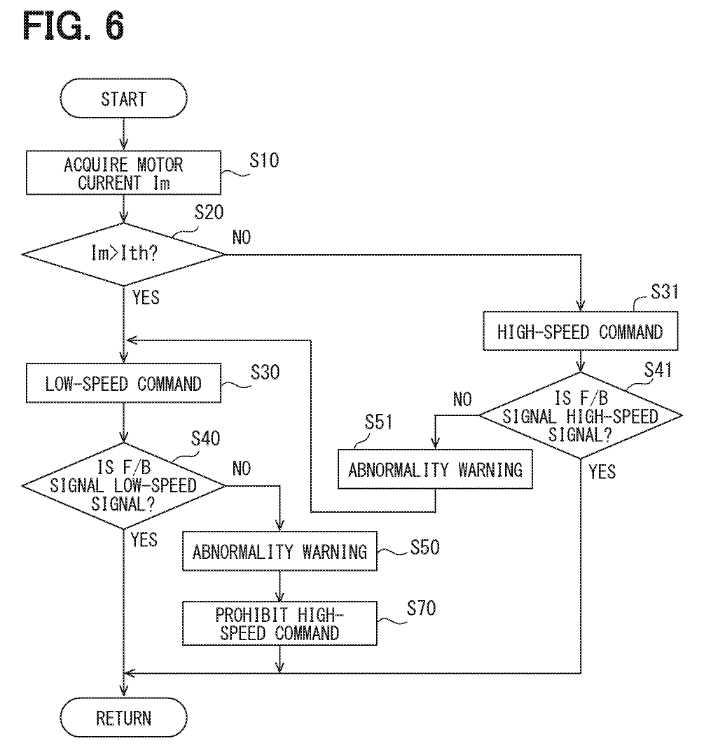

Specifically, when a negative determination is made in step S41 of FIG. 6, an abnormality flag is turned on in step S51, as in step S50, to issue an abnormality warning. Thereafter, in step S30, the low-speed signal is output as a speed command. That is, when it is determined that an abnormal state exists because the switching speed corresponding to the feedback signal is slower than the command speed, the speed command unit 35 changes the command speed to decrease it.

Thereafter, when the actual speed becomes normally low, an affirmative determination is made in step S40, and when the motor current Im remains below the threshold value Ith thereafter, the command speed is switched again to the high-speed command in step S31.

Furthermore, in the present embodiment, when the negative determination is made in step S40, the abnormality warning is issued in step S50, and then in the following step S70, the speed command unit 35 is prohibited from outputting a high-speed command.

### Summary of the Second Embodiment:

According to the present embodiment, it is possible to achieve the same effect as the configurations described in the preceding embodiments. In addition, the ECU 30 changes the command speed when it is determined that the abnormal state exists. More specifically, when the actual speed is low despite the high-speed command, that is, when the negative determination is made in step S41, the command is changed to a low-speed command. By changing from the high-speed command to the low-speed command in this way, it is possible to avoid an abnormal state. Therefore, according to the present embodiment, there are cases where the motor generator 3 can be switched to a state in which it is driven normally.

Furthermore, according to the present embodiment, when it is determined that the abnormal state exists, the ECU 30 fixes the command speed to a predetermined speed and prohibits any change thereto. More specifically, when the actual speed is high despite the low-speed command, that is, when a negative determination is made in step S40, the low-speed command is fixed and a change to the high-speed command is prohibited. This reduces the risk of the switching speed becoming unintentionally high, and reduces the risk of damage to the MOSFET 13 due to surge voltage.

### Third Embodiment

A second embodiment is a modification of the preceding embodiment as a basic configuration and may incorporate description of the precedent embodiments. In the previous embodiment, one type of feedback signal is used to diagnose an abnormality. Alternatively, two or more types of feedback signals may be used to diagnose the abnormality.

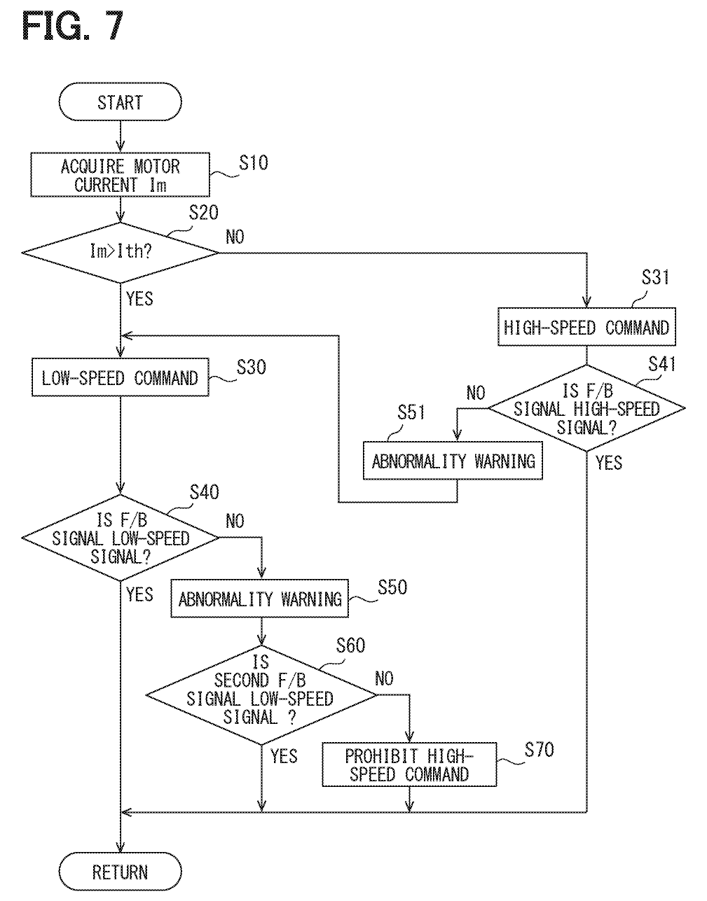

Specifically, in the present embodiment, as shown in FIG. 7, step S60 is added to the flowchart of FIG. 6. This step S60 is executed when the actual speed is high despite the low-speed command, that is, when the determination in step S40 is negative. In step S60, the monitoring unit 36 determines whether the abnormality has occurred using the second feedback signal. Specific examples of the second feedback signal include the element temperature T, the magnitude of the gate voltage applied to the gate terminal of the MOSFET 13, and the waveform of a surge voltage occurring in the MOSFET 13 or the winding 3a. In the present embodiment, the element temperature T is used as the second feedback signal. The first feedback signal is the switching signals VH and VL, whereas the element temperature T as the second feedback signal corresponds to the detection signal.

The first feedback signal is the feedback signal used in steps S40 and S41, that is, the switching signals VH and VL. The second feedback signal is a signal that is correlated with the actual switching speed and is different in type from the first feedback signal.

Steps S40 and S41 correspond to a first determination unit that determines the abnormal state using the first feedback signal. Step S60 corresponds to a second determination unit that determines whether an abnormal state exists using the second feedback signal. The temperature sensor 40 corresponds to a detection unit that detects the second feedback signal. This detection unit and feedback circuit 23 correspond to a feedback unit that outputs a feedback signal that is correlated with the actual switching speed.

Here, the faster the switching speed, the higher the element temperature T becomes. Therefore, when the speed command is switched from the high-speed command to the low-speed command and this state continues for a predetermined time or more, the element temperature T should decrease. Similarly, when the speed command is switched from the low-speed command to the high-speed command and this state continues for a predetermined time or more, the element temperature T should rise. In consideration of these points, in step S60, it is determined based on the element temperature T whether the actual speed is low or high. More specifically, the actual speed is determined based on the current value of the element temperature T and the change in the element temperature T up to the current time.

When it is determined in step S40 that the speed is not low even though the low-speed command is output in step S30, the abnormality flag is set to ON in step S50. However, even if such an abnormality is diagnosed, when it is determined in step S50 that the speed is low, the process returns to step S10 without prohibiting the high-speed command in step S70. When it is determined in step S50 that the speed is not low, as in step S40, the high-speed command is prohibited in step S70. Step S70 corresponds to a regulating unit that limits the command speed so as to prohibit the high-speed command when the second determination unit determines that the abnormal state exists.

### Summary of Third Embodiment:

According to the present embodiment, it is possible to achieve the same effect as the configurations described in the preceding embodiments. Additionally, the power conversion device 4 includes the temperature sensor 40, and the feedback signal includes the element temperature T detected by the temperature sensor 40 in addition to the switching signals VH and VL. The abnormality determination unit by the monitoring unit 36 includes the first determination unit by steps S40 and S41 and the second determination unit by step S60. The first determination unit determines whether an abnormal state exists by comparing the switching signals VH and VL with the command speed. The second determination unit determines whether an abnormal state exists by comparing the element temperature T detected by the temperature sensor 40 with the command speed. According to this, since the abnormality determination is performed using two types of feedback signals, the accuracy of the abnormality determination can be improved.

Here, although the first determination unit can quickly detect an abnormality, there may be cases where an erroneous detection occurs due to an abnormality in the signal line L3. In consideration of this point, in the present embodiment, even if the first determination unit determines that an abnormal state exists, when the second determination unit does not determine that an abnormal state exists, the regulating unit is prohibited from imposing a speed limit in step S70. This reduces the concern that excessive speed restrictions will prevent sufficient improvements in electricity efficiency. Therefore, it is possible to avoid failure of the MOSFET 13 and improve the power consumption at the same time.

### Other Embodiments:

The disclosure in this specification and drawings is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may have additional portions that may be added to the embodiments. The disclosure encompasses omission of components and/or elements of the embodiments. The disclosure encompasses the replacement or combination of components and/or elements between one embodiment and another. The disclosed technical scope is not limited to the description of the embodiments. The several technical scopes disclosed are indicated by the description of the claims, and should be further understood to include meanings equivalent to the description of the claims and all modifications within the scope.

The disclosure in the description, drawings and the like is not limited by the description of the claims. The disclosures in the specification, the drawings, and the like encompass the technical ideas described in the claims, and further extend to a wider variety of technical ideas than those in the claims. Hence, various technical ideas can be extracted from the disclosure of the description, the drawings, and the like without being bound by the description of the claims.

In the third embodiment, the first feedback signal and the second feedback signal are used to determine whether an abnormality has occurred. However, the first feedback signal may be eliminated, and the second feedback signal may be used to determine whether an abnormality has occurred.

In each of the above-described embodiments, the switching speed is switched between two stages: high-speed and low-speed. In contrast to this configuration, the switching speed may be changed in three or more stages, or may be changed linearly without stages.

In the second embodiment described above, in the case of an abnormal state, the ECU 30 fixes the command speed to a predetermined speed. Specifically, assuming that the switching speed is switched between two stages, high-speed and low-speed, in the event of an abnormality where the actual speed is high despite the low-speed command, the ECU 30 fixes the speed command to the low-speed command. On the other hand, assuming that the speed is switched between three levels, high-speed, medium speed, and low-speed, the ECU 30 may fix the speed to the low-speed command or the medium-speed command in the event of the above abnormality. Also, on the premise that the switching speed is changed linearly in a stepless manner, the ECU 30 may issue a speed command by fixing the speed at a level at which the MOSFET 13 will not be damaged. Specific examples of damage in this case include damage caused by an excessive current flowing through the MOSFET 13, damage caused by an excessive temperature of the MOSFET 13, and damage caused by an excessive voltage being applied to the MOSFET 13.

In each of the above-described embodiments, when a negative determination is made in step S41, if the motor current Im is thereafter greater than the threshold value Ith, the low-speed command is permitted in step S30. On the other hand, when a negative determination is made in step S41, the low-speed command may be prohibited regardless of the magnitude of the motor current Im thereafter.

In each of the above-described embodiments, when a negative determination is made in step S40, the switching speed is subsequently determined in step S20 according to the magnitude of the motor current Im. On the other hand, when a negative determination is made in step S40, the motor current Im may be fixed to the high-speed command regardless of the magnitude of the motor current Im thereafter.

In each of the above-described embodiments, the switching speed is changed in accordance with the motor current Im. On the other hand, the switching speed may be changed depending on the temperature of the MOSFET 13 or the temperature of the cooling water that cools the MOSFET 13. For example, the higher these temperatures are, the faster the switching speed is desired to reduce power loss. Furthermore, the switching speed may be changed depending on the voltage supplied to the MOSFET 13 and the voltage supplied to the drive circuit 20. For example, the lower these voltages, the faster the switching speed is desired to reduce power losses. Furthermore, the switching speed may be changed depending on the voltage of the power supply used as the gate signal of the MOSFET 13. For example, lower voltages for gate signals are desirable to increase switching speed and reduce power losses. Furthermore, the switching speed may be changed by combining parameters such as the motor current Im, various temperatures, various voltages, and atmospheric pressure.

The power conversion device 4 may further include a converter as the power conversion circuit. The converter is a DC-DC conversion circuit that converts a DC voltage, for example, to a DC voltage of a different value. The converter is provided between the DC power supply 2 and the smoothing capacitor 6. The converter is configured to include, e.g., a reactor and the above-mentioned upper and lower arm circuit 10. This configuration can boost and/or suppress voltage. The power conversion device 4 may further include a filter capacitor for removing power supply noise from the DC power supply 2. The filter capacitor is provided between the DC power supply 2 and the converter.

What is claimed is:

1. A power conversion device, comprising:
a plurality of switching elements configured to convert and output electric power;
a processor with a memory storing computer program code executable by the processor, the processor configured to cause the power conversion device to:
command a switching speed of the switching elements;
drive the switching element to turn on and off at a switching speed corresponding to a command speed;
output a signal correlated with an actual switching speed as a feedback signal; and
determine whether the actual switching speed is in an abnormal state contrary to the command speed by comparing the feedback signal with the command speed.

2. The power conversion device according to claim 1, wherein
the processor is further configured to cause the power conversion device to
change the command speed when the abnormal state is determined.

3. The power conversion device according to claim 2, wherein
the processor is further configured to cause the power conversion device to
change the command speed to decrease the command speed, when the abnormal state is determined due to the switching speed corresponding to the feedback signal being slower than the command speed.

4. The power conversion device according to claim 1, wherein
the processor is further configured to cause the power conversion device to
fix the command speed to a predetermined speed and prohibit a change of the command speed when the abnormal state is determined.

5. The power conversion device according to claim 1, wherein
the processor is further configured to cause the power conversion device to
switch a magnitude of a gate voltage and outputs the gate voltage to the switching element, and switch a switching speed by instructing the output circuit to which gate voltage to switch, wherein
the feedback signal includes a switching signal representing a command.

6. The power conversion device according to claim 5, wherein
the processor is further configured to cause the power conversion device to
detect at least one of a temperature of the switching element, a gate voltage applied to the switching element, and a surge voltage waveform of the switching element,
generate a detection signal,
determine the abnormal state by comparing the switching signal with the command speed, and
determine the abnormal state by comparing the detection signal with the command speed.

7. The power conversion device according to claim 6, wherein,
the processor is further configured to cause the power conversion device to
limit a command speed when determining the abnormal state by comparing the detection signal with the command speed, and
prohibit a speed limitation, even if determining the abnormal state by comparing the switching signal with the command speed, when determining that the abnormal state does not exist by comparing the detection signal with the command speed.

8. The power conversion device according to claim 1, wherein
the processor is further configured to cause the power conversion device to
command a common switching speed to the plurality of switching elements,
output the feedback signal for each of the plurality of switching elements, and
determine that the abnormal state exists when at least one of a plurality of feedback signals is contrary to the command speed.

9. A power conversion device, comprising:
a plurality of switching elements configured to convert and output electric power;
a control device configured to command a switching speed of the switching element;
a drive circuit configured to drive the switching element to turn on and off at a switching speed corresponding to a command speed from the control device;
a feedback unit that outputs a signal correlated with an actual switching speed as a feedback signal to the control device; and
an abnormality determination unit configured to determine whether the actual switching speed is in an abnormal state contrary to the command speed by comparing the feedback signal with the command speed.

10. The power conversion device according to claim 9, wherein
the control device changes the command speed when the abnormal state is determined.

11. The power conversion device according to claim 10, wherein
when the abnormal state is determined due to the switching speed corresponding to the feedback signal being slower than the command speed, the control device changes the command speed to decrease the command speed.

12. The power conversion device according to claim 9, wherein
the control device fixes the command speed to a predetermined speed and prohibits a change of the command speed when the abnormal state is determined.

13. The power conversion device according to claim 9, wherein
the drive circuit has an output circuit that switches a magnitude of a gate voltage and outputs the gate voltage to the switching element, and a switching circuit that switches a switching speed by instructing the output circuit to which gate voltage to switch, and
the feedback signal includes a switching signal representing a command issued by the switching circuit.

14. The power conversion device according to claim 13, wherein
the feedback unit includes a detection unit that detects at least one of a temperature of the switching element, a gate voltage applied to the switching element, and a surge voltage waveform of the switching element,
the feedback signal includes a detection signal detected by the detection unit in addition to the switching signal, and
the abnormality determination unit has a first determination unit that determines the abnormal state by comparing the switching signal with the command speed, and a second determination unit that determines the abnormal state by comparing the detection signal with the command speed.

15. The power conversion device according to claim 14, further comprising,
a regulating unit that limits a command speed from the control device when the second determining unit determines that the abnormal state exists, wherein
even if the first determination unit determines that the abnormal state exists, when the second determination unit does not determine that the abnormal state exists, the regulating unit prohibits speed limitation.

16. The power conversion device according to claim 9, wherein
the control device commands a common switching speed to the plurality of switching elements,
the feedback unit outputs the feedback signal for each of the plurality of switching elements, and
the abnormality determination unit determines that the abnormal state exists when at least one of a plurality of feedback signals is contrary to the command speed.
